(19) United States
(12) Patent Application Publication
(10) Pub. No.: US 2026/0023269 A1
(43) Pub. Date: Jan. 22, 2026

(54) DARK FIELD IMAGING SYSTEM WITH TWICE-DIFFRACTED LIGHT FOR OVERLAY METROLOGY

(71) Applicant: KLA Corporation, Milpitas, CA (US)

(72) Inventors: Wenjian Cai, Sunnyvale, CA (US); Xuefeng Liu, San Jose, CA (US); John Fielden, Los Altos, CA (US); Yung-Ho Alex Chuang, Cupertino, CA (US)

(21) Appl. No.: 19/269,752

(22) Filed: Jul. 15, 2025

Related U.S. Application Data
(60) Provisional application No. 63/673,804, filed on Jul. 22, 2024.

(51) Int. Cl. G02B 27/44; G01B 11/27; G03F 7/00

(52) U.S. Cl. CPC G02B 27/44; G01B 11/27; G03F 7/70633

(57) ABSTRACT

An overlay metrology system and method are disclosed. The overlay metrology system may be configured for twice-diffracted light. The overlay metrology system may include a controller. The controller may be configured to receive an image of a metrology target of a sample based on twice-diffracted light associated with one or more illumination beams in accordance with a metrology recipe. The twice-diffracted light may be based on a first diffraction, a re-direction, and a second diffraction of the one or more illumination beams directed twice towards the metrology target. The controller may be configured to generate one or more metrology measurements of the sample based on the image in accordance with the metrology recipe and based on a double-phase-shift of the twice-diffracted light associated with the one or more illumination beams.

### CROSS-REFERENCE TO RELATED APPLICATION

The present application claims the benefit under 35 U.S.C. § 119(e) of U.S. Provisional Application Ser. No. 63/673,804, filed Jul. 22, 2024, which is incorporated herein by reference in the entirety.

### TECHNICAL FIELD

The present disclosure relates generally to overlay metrology and, more particularly, to dark-field imaging overlay metrology.

### BACKGROUND

Overlay metrology refers to measurements of the relative alignment of layers on a sample such as, but not limited to, semiconductor devices. An overlay measurement, or a measurement of overlay error, typically refers to a measurement of the misalignment of fabricated features on two or more sample layers. Proper alignment of fabricated features on multiple sample layers may be necessary for proper functioning of the device.

Demands to decrease feature size and increase feature density are resulting in correspondingly increased demand for accurate and efficient overlay metrology systems. Metrology systems typically generate metrology data associated with a sample by measuring or otherwise inspecting overlay metrology targets distributed across the sample. Overlay metrology targets are typically used to measure the relative alignment between layers of interest of a sample based on target features located in the layers of interest. Further, the overlay alignment of the layers of interest is typically determined by aggregating overlay measurements of multiple overlay targets at various locations across the sample.

As the size of fabricated features decreases and the feature density increases, the demands on overlay metrology systems needed to characterize these features increase. In particular, smaller features require more sensitive and more accurate measurements of small alignment errors. Accordingly, it is desirable to develop systems and methods to address these demands.

### SUMMARY

An overlay metrology system is disclosed in accordance with one or more illustrative embodiments of the present disclosure. In one illustrative embodiment, the overlay metrology system may be configured for twice-diffracted light. In another illustrative embodiment, the overlay metrology system may include a controller configured to be communicatively coupled to a detector of an overlay metrology sub-system. In another illustrative embodiment, the controller may include one or more processors configured to execute program instructions causing the one or more processors to receive an image of a metrology target of a sample based on twice-diffracted light associated with one or more illumination beams in accordance with a metrology recipe. In another illustrative embodiment, the twice-diffracted light may be based on a first diffraction, a re-direction, and a second diffraction of the one or more illumination beams directed twice towards the metrology target. In another illustrative embodiment, the controller may generate one or more metrology measurements of the sample based on the image in accordance with the metrology recipe and based on a double-phase-shift of the twice-diffracted light associated with the one or more illumination beams.

In a further illustrative embodiment, the overlay metrology system may include one or more masks in the overlay metrology sub-system. In another illustrative embodiment, the one or more masks may be configured in accordance with the metrology recipe to pass a non-zero-order diffraction beam and block a zero-order diffraction beam associated with the twice-diffracted light of the one or more illumination beams.

In a further illustrative embodiment, the one or more illumination beams may include one or more pairs of mutually coherent illumination beams. In another illustrative embodiment, each illumination beam of the pairs of mutually coherent illumination beams may be configured to be received by a respective set of one or more optical assemblies.

In a further illustrative embodiment, the metrology target on the sample may include an AIM metrology target in accordance with the metrology recipe.

An overlay metrology system is disclosed in accordance with one or more illustrative embodiments of the present disclosure. In one illustrative embodiment, the overlay metrology system may be configured for twice-diffracted light. In another illustrative embodiment, the overlay metrology system may include an illumination source configured to generate illumination. In another illustrative embodiment, the overlay metrology system may include an objective lens configured to direct one or more illumination beams associated with the illumination to a metrology target on a sample. In another illustrative embodiment, the metrology target may be configured in accordance with a metrology recipe to include periodic features associated with two or more lithographic exposures. In another illustrative embodiment, the objective lens may be further configured to collect light associated with a first diffraction of the one or more illumination beams. In another illustrative embodiment, the overlay metrology system may include one or more optical assemblies configured to receive the light associated with the first diffraction of the one or more illumination beams and re-direct the light back towards the metrology target. In another illustrative embodiment, the objective lens may be further configured to collect twice-diffracted light associated with a second diffraction of the one or more illumination beams such that the light associated with the second diffraction comprises the twice-diffracted light. In another illustrative embodiment, the overlay metrology system may include a detector configured to generate an image of the metrology target based on the twice-diffracted light. In another illustrative embodiment, the overlay metrology system may include a controller communicatively coupled to the detector. In another illustrative embodiment, the controller may include one or more processors configured to execute program instructions causing the one or more processors to generate one or more metrology measurements of the sample based on the image in accordance with the metrology recipe.

In a further illustrative embodiment, the overlay metrology system may include one or more masks. In another illustrative embodiment, the one or more masks may be configured in accordance with the metrology recipe to pass a non-zero-order diffraction beam and block a zero-order diffraction beam associated with the twice-diffracted light of each of the one or more illumination beams.

In a further illustrative embodiment, the one or more masks may be located at or near a collection pupil of the overlay metrology system.

In a further illustrative embodiment, each of the one or more optical assemblies may include at least one focusing element.

In a further illustrative embodiment, the at least one focusing element may include at least one curved mirror.

In a further illustrative embodiment, the at least one focusing element may include at least one lens.

In a further illustrative embodiment, the one or more illumination beams may include one or more pairs of mutually coherent illumination beams. In another illustrative embodiment, each illumination beam of the pairs of mutually coherent illumination beams may be configured to be received by a respective set of one or more optical assemblies.

In a further illustrative embodiment, the metrology target on the sample may include an AIM metrology target in accordance with the metrology recipe.

A metrology method is disclosed in accordance with one or more illustrative embodiments of the present disclosure. In one illustrative embodiment, the method may include generating illumination with an illumination source. In another illustrative embodiment, the method may include directing one or more illumination beams associated with the illumination to a metrology target on a sample with an objective lens. In another illustrative embodiment, the metrology target may be configured in accordance with a metrology recipe to include periodic features associated with two or more lithographic exposures. In another illustrative embodiment, the method may include collecting light associated with a first diffraction of the one or more illumination beams with the objective lens. In another illustrative embodiment, the method may include receiving the light associated with the first diffraction of the one or more illumination beams with one or more optical assemblies. In another illustrative embodiment, the method may include re-directing the light associated with the first diffraction of the one or more illumination beams back towards the metrology target on the sample with the one or more optical assemblies. In another illustrative embodiment, the method may include collecting twice-diffracted light associated with a second diffraction of the one or more illumination beams with the objective lens such that the light associated with the second diffraction comprises the twice-diffracted light. In another illustrative embodiment, the method may include generating an image of the metrology target based on the twice-diffracted light associated with the second diffraction of the one or more illumination beams with a detector. In another illustrative embodiment, the method may include generating one or more metrology measurements of the sample based on the image in accordance with the metrology recipe with a controller communicatively coupled to the detector.

In a further illustrative embodiment, the method may include passing a non-zero-order diffraction beam associated with the twice-diffracted light of each of the one or more illumination beams with one or more masks. In another illustrative embodiment, the method may include blocking a zero-order diffraction beam associated with the twice-diffracted light of each of the one or more illumination beams with the one or more masks.

In a further illustrative embodiment, the one or more masks may be located at or near a collection pupil of an overlay metrology system.

In a further illustrative embodiment, each of the one or more optical assemblies may include at least one focusing element.

In a further illustrative embodiment, the at least one focusing element may include at least one curved mirror.

In a further illustrative embodiment, the at least one focusing element may include at least one lens.

In a further illustrative embodiment, the one or more illumination beams may include one or more pairs of mutually coherent illumination beams. In another illustrative embodiment, each illumination beam of the pairs of mutually coherent illumination beams may be configured to be received by a respective set of one or more optical assemblies.

In a further illustrative embodiment, the metrology target on the sample may include an AIM metrology target in accordance with the metrology recipe.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims. In the drawings:

FIG. 1 illustrates a block diagram illustrating an overlay metrology system, in accordance with one or more embodiments of the present disclosure.

FIG. 2 illustrates a simplified schematic view of an optical assembly configured to re-direct light, in accordance with one or more embodiments of the present disclosure.

FIG. 3A illustrates a simplified schematic view of an overlay metrology system including one illumination beam, in accordance with one or more embodiments of the present disclosure.

FIG. 3B illustrates a top view of a collection pupil for the illumination beam of FIG. 3A, in accordance with one or more embodiments of the present disclosure.

FIG. 4A illustrates a simplified schematic view of an overlay metrology system including two illumination beams, in accordance with one or more embodiments of the present disclosure.

FIG. 4B illustrates a top view of a collection pupil for the two illumination beams of FIG. 4A, in accordance with one or more embodiments of the present disclosure.

FIG. 5 illustrates a simplified schematic view of an overlay metrology system that includes one optical assembly, in accordance with one or more embodiments of the present disclosure.

FIG. 6 illustrates a top view of an AIM overlay target, in accordance with one or more embodiments of the present disclosure.

FIG. 7 illustrates a flow diagram illustrating a method, in accordance with one or more embodiments of the present disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

Typically, in image-based overlay (IBO), grating target pairs at different layers of devices of a sample (e.g., wafer) are imaged and relative position between the pairs, or overlay, is derived. In order to measure a small overlay, grating targets with small pitches are typically utilized to achieve high sensitivity. A high numerical aperture (NA) objective may be used in conventional systems to resolve these gratings.

In some IBO overlay metrology techniques, the measurement of phase shift, rather than only intensity, enables the determination of overlay to determine relative alignment between different patterned layers of a sample. By analyzing a relative displacement of a signal in terms of its phase, the overlay between layers may be quantified. The relative phase shift measured between corresponding grating structures directly correlates to the positional offset, enabling overlay determination.

Embodiments of the present disclosure are directed to systems and methods for overlay metrology configured to diffract the same light twice to double the amount of phase-shift measurable during an overlay metrology measurement. The system may include one or more optical assemblies to re-direct light that was diffracted from a sample a first time back towards the same sample to be diffracted a second time. In embodiments, the twice-diffracted light is used to generate an image of an overlay metrology target to measure the overlay of the sample. In embodiments, a zero-order portion of the twice-diffracted light is blocked by a mask, and at least one non-zero-order portion of the twice-diffracted light is imaged with a sensor.

The final image formed by the interference of the twice-diffracted beam may be analyzed to derive the overlay by calculating the relative phase of the two fringe patterns between the two layers. Due to being twice-diffracted, the phase difference may include a double-phase-shift compared to more conventional images formed by single diffractions.

It is contemplated herein that overlay metrology based on twice-diffracted light may improve sensitivity relative to existing image-based overlay metrology techniques based on light that is only diffracted once. Specifically, the doubled phase-shift of twice-diffracted light may provide a sensitivity that is twice as high, at the expense of increased light loss due to the additional second reflection and diffraction by the grating targets.

Embodiments herein may use any suitable configuration of a system configured for twice-diffracted light including a single illumination beam or two or more illumination beams.

Overlay metrology using pairs of mutually coherent illumination beams generated by a light source is disclosed in U.S. patent application Ser. No. 18/978,376, filed Dec. 12, 2024, which is hereby incorporated by reference in the entirety.

Overlay metrology using pairs of mutually coherent illumination beams generated by a coherent light source is disclosed in U.S. Pat. No. 12,032,300, entitled “Imaging overlay with mutually-coherent oblique illumination” and issued on Jul. 9, 2024, and U.S. patent application Ser. No. 18/742,869, entitled “Imaging overlay with mutually-coherent oblique illumination” and filed on Jun. 13, 2024, which are both herein incorporated by reference in their entirety.

In some embodiments, an overlay metrology tool is configured (e.g., according to a metrology recipe) to image a metrology target having periodic structures using non-zero diffraction which has been diffracted off a sample twice. Further, overlay may be determined by comparing relative phases of various imaged sinusoidal patterns of a metrology target. An overlay metrology system may be configured in multiple ways in accordance with the systems and method disclosed herein. In some embodiments, an overlay metrology system is configured to direct one or more illumination beams to a metrology target twice, with a numerical aperture (NA) of an objective lens used to collect light from the metrology target for imaging. In some embodiments, an overlay metrology system is configured to direct a pair of mutually-coherent illumination beams to a metrology target twice. In these configurations, the overlay metrology system may include one or more elements to block zero-order diffraction such that it does not contribute to image formation.

In some embodiments, the overlay metrology measurements are used to generate correctables to control one or more additional process tools such as, but not limited to, a lithography tool, an etching tool, or a polishing tool.

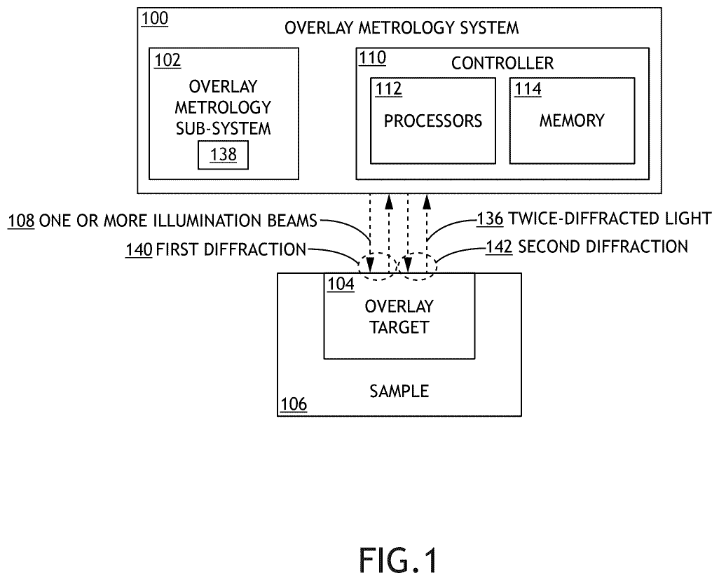

FIG. 1 illustrates a block diagram illustrating an overlay metrology system 100, in accordance with one or more embodiments of the present disclosure.

A metrology target and/or an overlay metrology tool suitable for characterizing the metrology target may be configured according to a metrology recipe suitable for generating overlay measurements based on a desired technique. More generally, an overlay metrology tool may be configurable according to a variety of metrology recipes to perform overlay measurements using a variety of techniques and/or perform overlay measurements on a variety of metrology targets with different designs.

For example, a metrology recipe may include various aspects of a metrology target or a design of a metrology target including, but not limited to, a layout of target features on one or more sample layers, feature sizes, or feature pitches. As another example, a metrology recipe may include illumination parameters such as, but not limited to, an illumination wavelength, an illumination pupil distribution (e.g., a distribution of illumination angles and associated intensities of illumination at those angles), a polarization of incident illumination, a spatial distribution of illumination, or a sample height. By way of another example, a recipe of an overlay metrology tool may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, or wavelength filters.

In embodiments, the overlay metrology system 100 includes an overlay metrology sub-system 102 configured to illuminate a metrology target 104 on a sample 106 with one or more illumination beams 108. In particular, the overlay metrology system 100 may be configured for a first diffraction 140 of the one or more illumination beams 108 at the metrology target 104 and a re-direction of light collected from the first diffraction 140 using one or more optical assemblies 138. After the re-direction using the one or more optical assemblies 138, the overlay metrology system 100 may be configured so that the re-directed light undergoes a second diffraction 142 at the same metrology target 104. The overlay metrology system 100 may be configured to image the twice-diffracted light 136 collected from the second diffraction using a detector.

In embodiments, the sample 106 may be disposed on a sample stage (not shown) suitable for securing the sample 106 and further configured to position the metrology target 104 with respect to the illumination beams 108.

The metrology target 104 may include various periodic features, which may have a periodicity. In embodiments, the metrology target 104 may have periodic features that have a periodicity along a single measurement direction (e.g., an x-direction or a y-direction). In embodiments, the metrology target 104 may include a first set of periodic features along a first measurement direction (e.g., an x-direction) and a second set of periodic features along a second measurement direction (e.g., a y-direction).

In embodiments, the periodic features of the metrology target 104 may be arranged into two or more target cells.

It is contemplated herein that various metrology target designs are suitable for overlay measurements with twice-diffracted light 136 as disclosed herein.

In embodiments, the overlay metrology system 100 includes a controller 110 communicatively coupled to the overlay metrology sub-system 102. The controller 110 may be configured to direct the overlay metrology sub-system 102 to generate images (e.g., dark-field images) based on one or more selected metrology recipes. The controller 110 may be further configured to receive data including, but not limited to, the images from the overlay metrology sub-system 102. Additionally, the controller 110 may be configured to determine overlay associated with a metrology target 104 based on the acquired images. As another example, the controller 110 may generate correctables to control, based on the overlay metrology measurements, one or more process tools such as, but not limited to, a lithography tool, an etching tool, or a polishing tool. Correctables may be generated to control one or more process tools in any combination of a feedback control loop or a feed-forward control loop. As an illustration, feedback correctables generated in response to metrology measurements on a sample 106 may control a process tool during the fabrication of additional samples in the same or different lots (e.g., in response to drifts of the process tools). As another illustration, feed-forward correctables generated in response metrology measurements on a sample 106 may be used to control a process tool during fabrication of additional features on the sample 106 in future process steps.

In some embodiments, the controller 110 includes one or more processors 112. For example, the one or more processors 112 may be configured to execute a set of program instructions maintained in a memory 114, or memory device.

The one or more processors 112 of a controller 110 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 112 may include any device configured to execute algorithms and/or instructions (e.g., program instructions stored in memory). In embodiments, the one or more processors 112 may be embodied as a desktop computer, mainframe computer system, workstation, image computer, parallel processor, networked computer, or any other computer system configured to execute a program configured to operate or operate in conjunction with the overlay metrology system 100, as described throughout the present disclosure. Moreover, different subsystems of the overlay metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 110 may include one or more controllers housed in a common housing or within multiple housings. In this way, any controller or combination of controllers may be separately packaged as a module suitable for integration into the overlay metrology system 100.

The memory 114 may include any storage medium known in the art suitable for storing program instructions executable by the associated one or more processors 112. For example, the memory 114 may include a non-transitory memory medium. By way of another example, the memory 114 may include, but is not limited to, a read-only memory (ROM), a random-access memory (RAM), a magnetic or optical memory device (e.g., disk), a magnetic tape, a solid-state drive, and the like. It is further noted that the memory 114 may be housed in a common controller housing with the one or more processors 112. In some embodiments, the memory 114 may be located remotely with respect to the physical location of the one or more processors 112 and the controller 110. For instance, the one or more processors 112 of the controller 110 may access a remote memory (e.g., server), accessible through a network (e.g., internet, intranet, and the like).

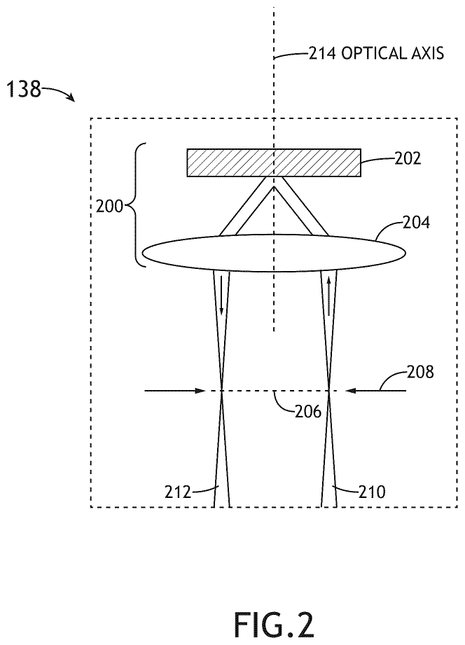

FIG. 2 illustrates a simplified schematic view of an optical assembly 138 configured to re-direct light, in accordance with one or more embodiments of the present disclosure. Once-diffracted light 210 collected/received by the optical assembly 138 is re-directed back towards the sample (not shown) as re-directed light 212. The once-diffracted light 210 may be referred to as light associated with the first diffraction 140.

Each of the one or more optical assemblies 138 may include at least one focusing element 200. The focusing element 200 may include at least one lens 204, such as a tube lens. The focusing element 200 may include one or more mirrors 202. In embodiments, the optical assembly 138 may include both a lens 204 and a mirror 202.

Note that the mirror 202 shown in FIG. 2 is simplified for illustration purposes only, and any suitable mirror 202 may be used. The mirror 202 may include two or more mirrors. The mirror 202 may include a single mirror such as a flat or curved mirror. For example, to remove color aberration and make the assembly a shorter distance, the mirror 202 may include a spherical mirror.

The mirror 202 may be located at a back focal plane of the lens 204. The lens 204 may be located such that a front focal plane of the lens 204 is positioned at a collection pupil 206 of the once-diffracted light 210 of the metrology sub-system 102.

In embodiments, the optical assembly 138 is spaced laterally (e.g., to the left) relative to a direction of travel of the once-diffracted light 210 received from the sample. In this way, the once-diffracted light 210 is offset laterally from an optical axis 214 of the optical assembly 138. In embodiments, the re-directed light 212 forms an image of the once-diffracted light 210 at the collection pupil 206, where the two lights 210, 212 are symmetrically positioned relative to the optical axis 214 of the optical assembly 138. Moreover, each ray in the re-directed light 212 may propagate exactly opposite to rays in the original once-diffracted light 210 in terms of angles relative to the collection pupil 206. Such an opposite and symmetrical configuration may ensure that the second diffraction 142 of the re-directed light 212 at the sample 106 occurs at a same field point on the metrology target 104 as the first diffraction 140 occurred. Note that the optical assembly 138 shown in FIG. 2 is for illustration purposes only, and any suitable optical assembly 138 configured to re-direct light may be used.

In embodiments, the overlay metrology sub-system 102 includes a folded 4f optical sub-system.

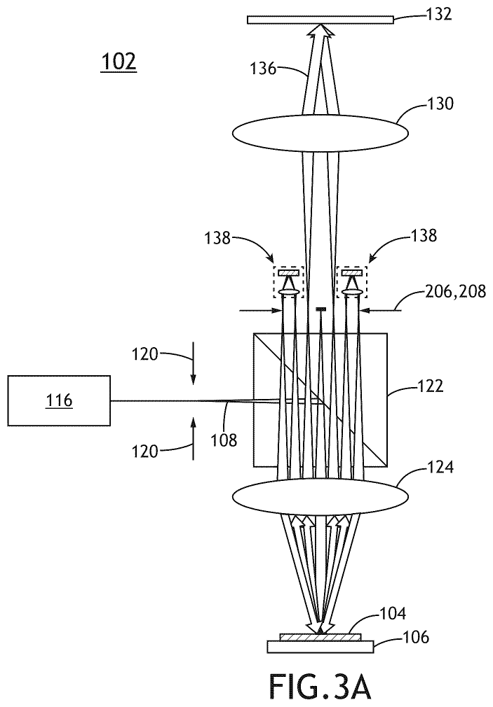

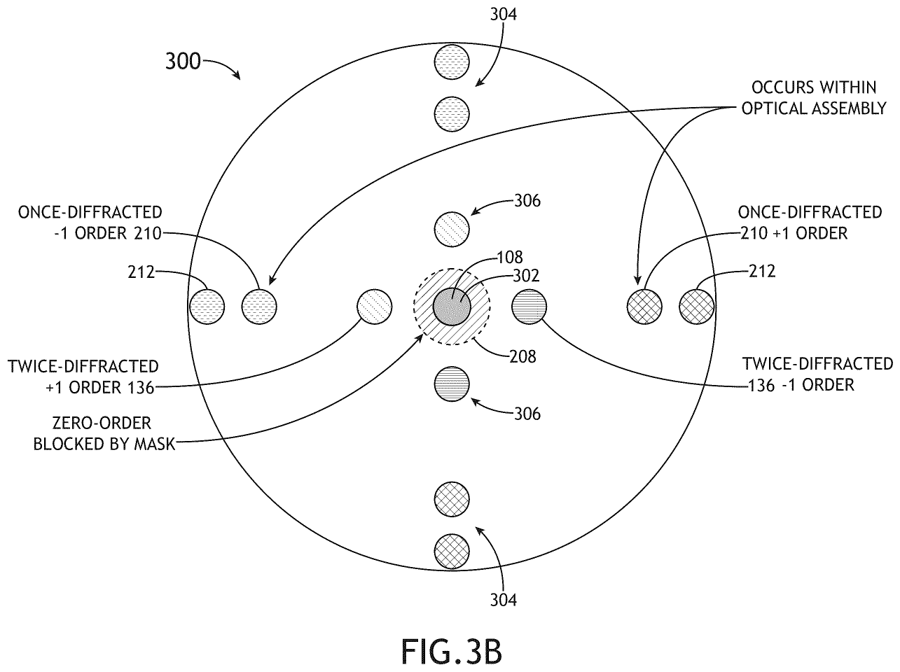

FIG. 3A illustrates a simplified schematic view of an overlay metrology system 100 including one central illumination beam 108, in accordance with one or more embodiments of the present disclosure.

In embodiments, the overlay metrology sub-system 102 includes one or more optical elements configured to combine an illumination pathway with a collection pathway such that an objective lens 124 may both direct the one or more illumination beams 108 to the metrology target 104 and collect associated diffracted light (e.g., twice-diffracted light 136). Put another way, such optical elements may enable through-the-lens (TTL) illumination and imaging with the objective lens 124.

In embodiments, the illumination path includes the illumination source 116, a beam splitter 122, and the objective lens 124.

In embodiments, the collection path includes the objective lens 124, the beam splitter 122, one or more optical assemblies 138, one or more masks 208 at a collection pupil 206, a tube lens 130, and a detector 132.

In embodiments, the overlay metrology sub-system 102 includes an illumination pupil 120, wherein an illumination beam 108 passes through the illumination pupil 120.

In embodiments, the objective lens 124 may direct the one or more illumination beams 108 to a metrology target 104 on a sample 106. Additionally, the objective lens 124 may direct twice-diffracted light 136 associated with the one or more illumination beams 108 to a detector 132.

In embodiments, the overlay metrology sub-system 102 includes the detector 132. The detector 132 may be configured to generate an image of the metrology target 104 based on light (e.g., twice-diffracted light 136 of the sample 106). The detector 132 may be communicatively coupled to the controller 110. The one or more processors 112 of the controller 110 may be configured to execute one or more sets of program instructions which may cause the one or more processors 112 to generate one or more metrology measurements of the sample 106 based on the image, in accordance with the metrology recipe.

In embodiments, the overlay metrology sub-system 102 includes a tube lens 130. The tube lens 130 may be positioned near the detector 132 and be configured to direct the twice-diffracted light 136 to the detector 132.

In embodiments, the overlay metrology sub-system 102 includes a beam splitter 122 to direct the one or more illumination beams 108 to the objective lens 124 and pass twice-diffracted light 136 collected by the objective lens 124 towards the detector 132.

In embodiments, the overlay metrology sub-system 102 includes an illumination source 116. The illumination source 116 may be configured to generate illumination. The illumination source 116 may be any illumination source 116 known in the art suitable for generating illumination. For example, the illumination source 116 may be a lamp source (e.g. a laser-sustained plasma light source), a supercontinuum source, a laser source, or a broadband illumination source. By way of another example the illumination source 116 may be an incandescent light bulb (e.g., a traditional tungsten filament bulb), fluorescent lights, or most light emitting diode (LED) lights. A singular illumination source 116 may generate the entirety of the light used to illuminate the sample 106. In embodiments, the illumination source 116 may be configured to generate temporally coherent illumination either directly or using a filter (e.g., a spectral filter to control a bandwidth). Any number of intermediate optical elements (e.g., diffraction gratings, lenses, and the like) may be used to output illumination beams 108 from the illumination source 116.

The illumination beams 108 at the entrance pupil of the objective lens 124 may form a Kohler illumination coupled through the beam splitter 122 to the metrology target 104 of the sample 106. The one or more optical assemblies 138 may return diffraction orders back toward the sample 106 and shift a position of the re-directed beams at the collection pupil 206 relative to the once-diffracted beams while maintaining the angles of the returned beams to be the same value as the original beams but in the opposite direction. The two re-directed beams may diffract off the grating targets for a second time and the subsequent twice-diffracted light 136 may form two diffraction orders shifted laterally from the original once-diffracted orders at the collection pupil 206.

In embodiments, the overlay metrology sub-system 102 includes one or more masks 208. The one or more masks 208 may be configured in accordance with the metrology recipe to pass a non-zero-order diffraction beam (e.g., a +1 order diffraction beam or a −1 order diffraction beam) and block a zero-order diffraction beam associated with the twice-diffracted light 136 of each of the one or more illumination beams 108.

At least one mask 208 may be placed at the collection pupil 206 to block the residual zero order light reflected from the grating targets. Therefore, a dark field image may be produced by the detector because the zero-order diffraction is blocked by the mask 208.

The one or more masks 208 may include any component or combination of components suitable for selectively passing a diffracted light associated with each of the illumination beams 108. For example, a first-order diffraction beam, a second-order diffraction beam, or the like may be passed while zero-order diffraction beams associated with the illumination beam 108 may be blocked. Furthermore, the one or more masks 208 may be placed at any suitable location in the overlay metrology sub-system 102.

In embodiments, the mask 208 is located at a collection pupil 206. For example, a mask 208 located at a collection pupil 206 may include one or more apertures surrounded by opaque portions, where desired diffraction orders may pass through the one or more apertures of the mask 208 while the opaque portions may block the zero-order diffraction beams as well as any other undesired light. As an illustration, a mask 208 located at a collection pupil 206 may have an annular aperture to pass desired diffraction orders to the detector.

FIG. 3B illustrates a top cross-sectional view 300 of the collection pupil 206 associated with FIG. 3A, in accordance with one or more embodiments of the present disclosure.

As shown, the mask 208 may be configured to block a zero-order light 302 reflecting off the sample from reaching the detector. For example, in a configuration with a single, central illumination beam 108, the mask 208 may include a central shape (e.g., circle) configured to selectively block the zero-order light 302 and allow one or more non-zero orders of twice diffracted light 136 to pass. For example, only the twice-diffracted +1 order light 136 and the twice-diffracted −1 order light 136 may be allowed to pass to the detector.

All other diffracted beams may be either blocked by the mask 208 or diffracted outside the objective lens 124 and the collection pupil 206. This results in a dark field image of the metrology target 104 to be formed, as no zero-order diffracted beam reaches the detector.

Also shown are diffraction orders 304 for a second measurement direction of interest, such as a y-direction of gratings orthogonal to an x-direction of gratings. The diffraction orders 304 for a second measurement direction of interest may include other twice-diffracted light 306 corresponding to +1 and −1 diffraction orders corresponding to gratings aligned in a second direction.

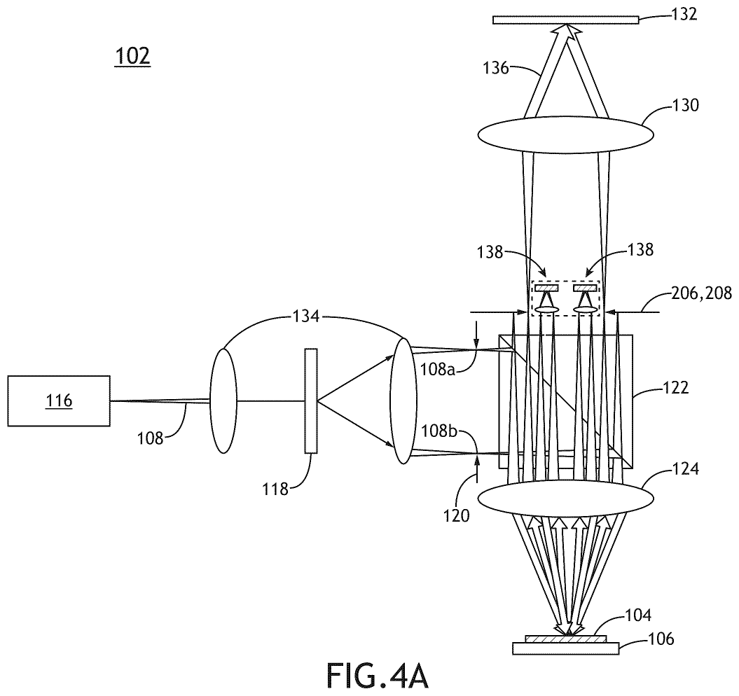

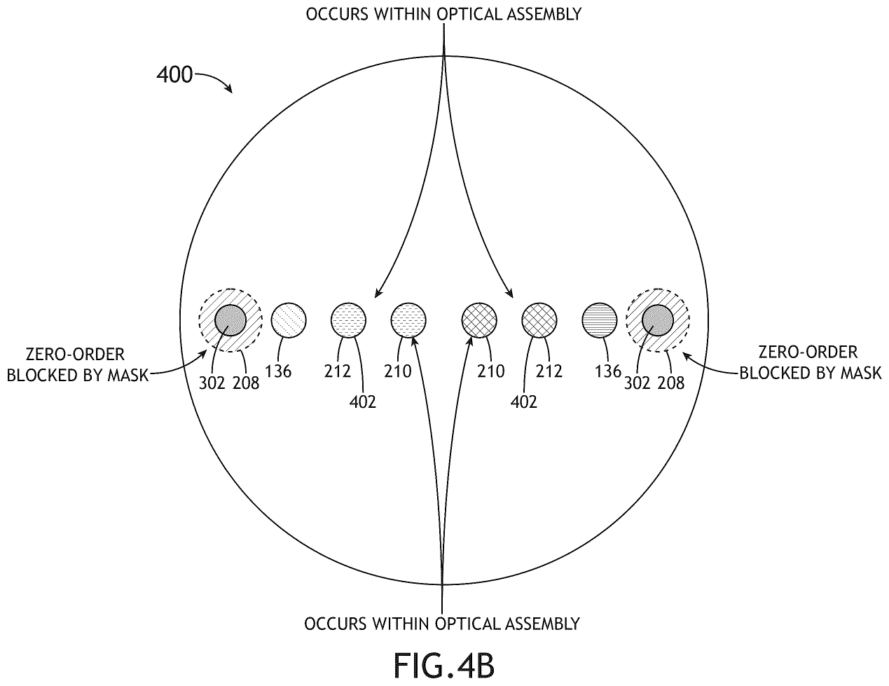

FIG. 4A illustrates a simplified schematic view of an overlay metrology system 100 including two illumination beams 108, in accordance with one or more embodiments of the present disclosure. Compared to the single illumination beam 108 of FIGS. 3A through 3B, FIG. 4A is an example of an alternate implementation of twice-diffracted light using a pair of mutually coherent illumination beams 108a, 108b output using modified illumination.

In embodiments, the overlay metrology sub-system 102 includes one or more illumination optics 134. For example, each of the illumination optics 134 may include, but is not required to include, one or more illumination lenses (e.g., to control a spot size of the illumination beam 108 on the metrology target 104, to relay pupil and/or field planes, or the like), one or more polarizers to adjust the polarization of the illumination beam 108, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The method of twice-diffracted dark field imaging to increase the sensitivity of overlay disclosed herein may also be applied to the mutually coherent dark field overlay disclosed in U.S. patent application Ser. No. 18/978,376, filed Dec. 12, 2024, which is hereby incorporated by reference in the entirety.

For example, two mutually-coherent illumination beams 108a, 108b may form at the entrance pupil of the objective lens 124 by virtue of a diffraction element 118 at the field stop of the illumination optics 134 that relays the illumination beam 108 from the illumination source 116 to the entrance pupil. The subsequent light of the first diffraction of the two mutually-coherent illumination beams 108a, 108b off the metrology target of the sample 106 is then re-directed back to the sample 106 by two optical assemblies 138 and is diffracted for a second time by the metrology target similar to the case described in FIG. 3A.

In embodiments, each illumination beam 108a, 108b of the one or more pairs of the mutually coherent illumination beams 108a, 108b is configured to be received by a respective set of one or more optical assemblies 138. For example, each set may include two or more optical assemblies 138, one for a +1 diffraction order and another one for a −1 diffraction order. However, note that such a configuration is merely an example and any suitable number and arrangement of optical assemblies 138 may be used.

In embodiments, the illumination source 116 may include any suitable illumination source configured to generate mutually-coherent illumination beams 108a, 108b (e.g., illumination beams 108a, 108b that are at least temporally coherent).

For example, the one or more pairs of mutually-coherent illumination beams 108a, 108b may be generated using a splitter element 118. The splitter element 118 may be configured to split an illumination beam 108 from the illumination source 116 into the one or more pairs of mutually-coherent illumination beams 108a, 108b. The splitter element 118 may include a diffraction grating. In embodiments, the diffraction grating is configured as any type of reflective or transmissive grating. For example, the diffraction grating may be a phase grating. The diffraction grating may be located at a field plane conjugate to the sample 106.

The diffraction grating of the splitter element 118 may be segmented to have different properties (e.g., pitch or orientation). This may permit different areas (e.g., different metrology targets 104) on a sample 106 to be illuminated by independent off-axis illumination. Multiple diffraction gratings may also be arranged on a slide or a wheel to provide additional configurations of off-axis illumination.

As noted, the illumination source 116 may be configured to generate one or more illumination beams 108. For the case of mutually-coherent illumination beams 108a, 108b, temporally coherent illumination may be used because the bandwidth may need to be controlled to allow interference across the whole field. For twice diffracted light, the resulting shift of diffracted and re-directed diffraction orders may not scale well with changes in wavelength. However, in embodiments, the temporally coherent illumination may still be spatially incoherent. The illumination source 116 may be any illumination source 116 known in the art suitable for generating temporally coherent illumination. For example, the illumination source 116 may include a highly temporally coherent illumination source (e.g., narrowband laser illumination source) to generate the temporally coherent illumination directly. By way of another example, the illumination source 116 may include an incoherent source and a filter or the like. In this way, temporally coherent illumination may be provided using incoherent illumination and a filter. The filter may include any suitable filter such as a spectral filter configured to control the bandwidth across the field. For instance, the illumination source 116 may be a lamp source (e.g. a laser-sustained plasma light source), a supercontinuum source, or a broadband illumination source (e.g., when the objective lens 124 is corrected for chromatic aberration and the image is color-corrected). In another instance, the illumination source 116 may be an incandescent light bulb (e.g., a traditional tungsten filament bulb), fluorescent lights, or most light emitting diode (LED) lights. A singular illumination source 116 may generate the entirety of the light used to illuminate the sample 106.

FIG. 4B illustrates a top view of a collection pupil 400 for the two illumination beams 108 of FIG. 4A, in accordance with one or more embodiments of the present disclosure.

As shown, the mask 208 may be configured to block a zero-order light 302 that reflects from the sample due to a first diffraction from reaching the detector. For example, in a configuration with a pair of mutually-coherent illumination beam 108, the mask 208 may include one or more shapes (e.g., two circles as shown; an annular ring; or the like) configured to selectively block the zero-order light 302 due to the first diffraction and allow one or more non-zero orders of twice-diffracted light 136 to pass. For instance, only the twice-diffracted +1 order light 136 and the twice-diffracted −1 order light 136 may be allowed to pass to the detector.

All other diffracted beams may be either blocked by the mask 208 or diffracted outside the collection pupil 206.

In embodiments, due to symmetry about a central optical axis, each re-directed light 212 of once-diffracted light re-directed back towards the sample may overlap with a zero-order 402 of twice-diffracted light associated with an opposite re-directed light 212 of once-diffracted light. For example, the term “once-diffracted light” 210 may refer to one or more non-zero orders (e.g., +1 order, −1 order) of once-diffracted light that are re-directed back towards the sample as re-directed light 212. Each re-directed light 212 may then undergo a second diffraction. The zero order of that second diffraction of that particular re-directed light 212 may be collected on the opposite side of the optical axis and be referred to as a zero-order 402 of twice-diffracted light. This zero-order 402 of twice-diffracted light may, due to symmetry about a central optical axis, overlap the other re-directed light 212 of once-diffracted light, although directed in an opposite direction.

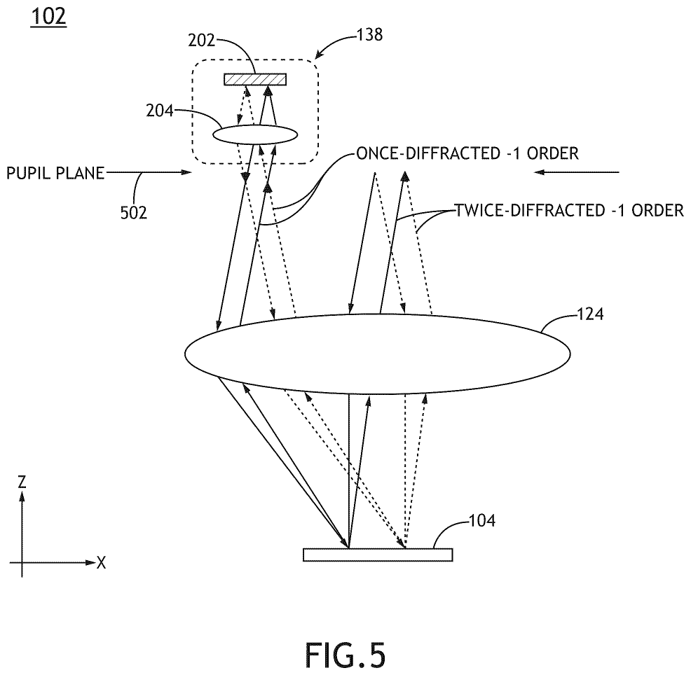

FIG. 5 illustrates a simplified schematic view of an overlay metrology system 100 that includes one optical assembly 138, in accordance with one or more embodiments of the present disclosure.

Various equations may describe the conditions of the overlay metrology system 100 shown in FIG. 5.

The illumination input may be given as:

$${e}^{- ik z} \qquad ( 1 )$$

The illumination of the 0-order at the sample (z=0) upon reflection is:

$${e}^{- ik z} = 1 \qquad ( 2 )$$

The illumination of the −1 order upon the first diffraction is:

$$1 * {e}^{- {ik}_{x} x} * {e}^{{ik}_{z} z} = {e}^{- {ik}_{x} x + {ik}_{z} z} \qquad ( 3 )$$

where kₓ is the x component of wave vector equal to 2π/Λ, where Λ is the grating pitch, and k_{z} is the z component of wave vector equal to \sqrt{k²−kₓ²}, where k is the magnitude of wave vector equal to 2π/λ, where λ is the wavelength.

The illumination after re-direction and the objective lens is:

$${e}^{i ( {k}_{x} + Δ k ) x - {ik}_{{z}^{′}} z + φ} \qquad ( 4 )$$

where Δk is the change of kₓ after the optical assembly, k_{z}, is the z component of wave vector equal to \sqrt{k²−(kₓ+Δk)²}, and φ is the phase delay from the sample to the re-direction and back to the sample.

The illumination of the 0-order upon reflection during the second diffraction at the sample is:

$${e}^{i ( {k}_{x} + Δ k ) x + {ik}_{{z}^{′}} z + φ} \qquad ( 5 )$$

The illumination of the −1 order upon the second diffraction is:

$${e}^{i ( {k}_{x} + Δ k ) x + {ik}_{{z}^{′}} z + φ} * {e}^{- {ik}_{x} x} * {e}^{i Δ {k}_{{z}^{′}} z} = {e}^{i Δ kx + {ik}_{{z}^{″}} z + φ} \qquad ( 6 )$$

where k_{z″} is the z component of wave vector equal to \sqrt{k²−Δk²}.

In the case of there being a E shift of the grating of the metrology target, an additional 2*kₓε phase will be picked up upon two diffractions at the grating.

In the case of there being the ε shift, the illumination of the −1 order upon diffraction is:

$$1 * {e}^{- {ik}_{x} ( x - ε )} * {e}^{{ik}_{{z}^{z}}} = {e}^{- {ik}_{x} x + {ik}_{z} z + {ik}_{x} ε} \qquad ( 7 )$$

In the case of there being the E shift, the illumination of the −1 order upon the second diffraction is:

$${e}^{i ( {k}_{x} + Δ k ) x + {ik}_{{z}^{′}} z + φ} * {e}^{- {ik}_{x} ( x - ε )} * {e}^{i Δ {k}_{z} z} = {e}^{i Δ kx + {ik}_{{z}^{″}} z + φ + {ik}_{x} ε} \qquad ( 8 )$$

The metrology sub-system 102 may include a mask 502 at a pupil plane of the metrology sub-system 102.

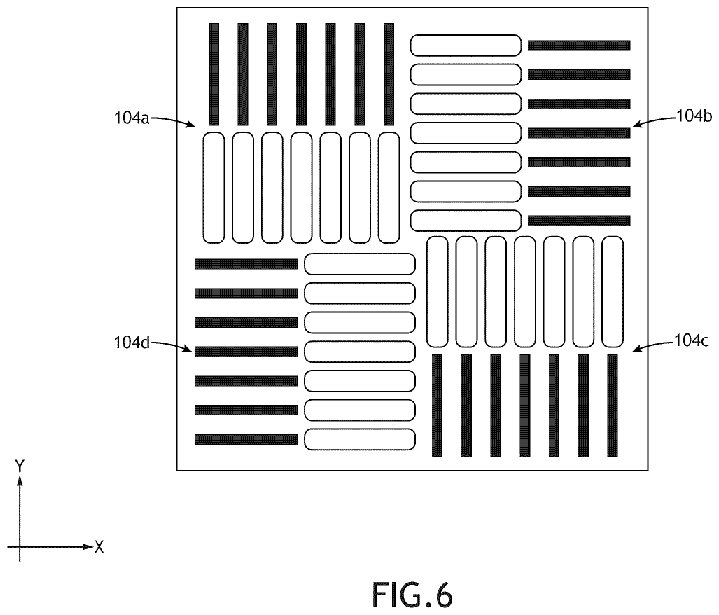

FIG. 6 illustrates a non-limiting example of a metrology target suitable for the various system configurations and overlay techniques described in FIGS. 3A through 4B.

FIG. 6 illustrates an AIM metrology target, in accordance with one or more embodiments of the present disclosure.

The overlay metrology sub-system 102 may image a metrology target 104 based on a non-zero diffraction associated with each illumination beam 108. In this way, the overlay metrology sub-system 102 may provide a dark-field image since zero-order diffraction of the illumination beams 108 does not contribute to image formation. Further, in embodiments where pairs of illumination beams 108 are mutually-coherent, diffraction lobes associated with each illumination beam 108 in the pair interferes with its counterpart to form a sinusoidal interference pattern in the image. As a result, the various grating structures in the metrology target 104 may be imaged with high contrast as pure sinusoids such that overlay measurements may be generated based on comparisons of relative phases of the neighboring cell images in accordance with a metrology recipe. In an AIM metrology target 104, the gratings may be located side by side in each cell 104a,b,c,d. A cell of the AIM metrology target 104 may include grating structures from different lithographic exposures in non-overlapping regions on one or more layers, where the grating structures from the different lithographic exposures have the same pitch.

In embodiments, the AIM metrology target 104 includes periodic features arranged into four target cells 104a,b,c,d. To correspond to the four target cells 104a,b,c,d on the metrology target 104, a diffraction grating of the splitter element 118 in FIG. 4A may include four respective diffraction grating cells (not shown).

Additionally, the periodic features in the metrology target 104 in FIG. 6 are arranged in two directions. Target cells 104a and 104c share a common direction of periodicity (e.g., the x-direction) and target cells 104b and 104d share a common direction of periodicity (e.g., the y-direction). The diffraction grating of the splitter element 118 may be designed to correspond to these directions of periodicity.

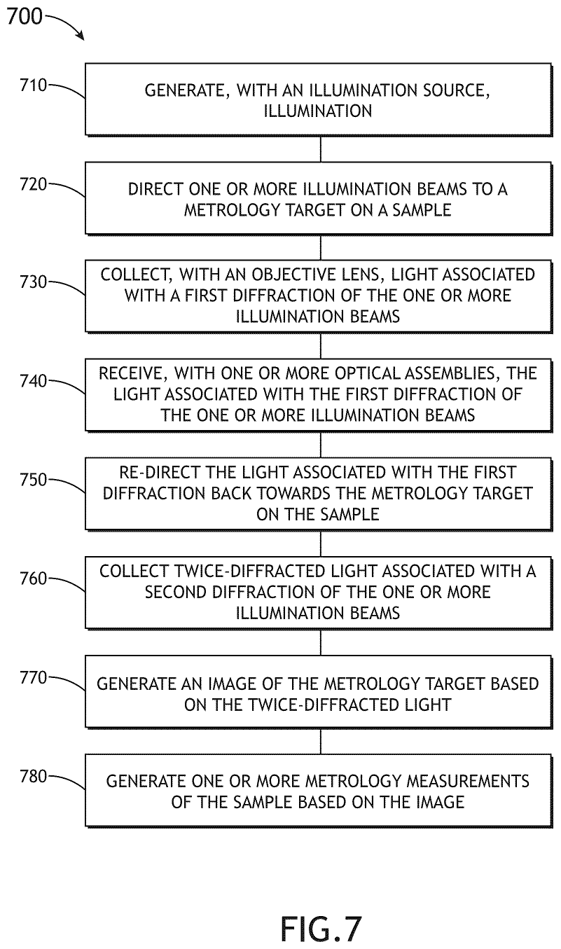

FIG. 7 illustrates a flow diagram illustrating a method, in accordance with one or more embodiments of the present disclosure. Applicant notes that the embodiments and enabling technologies described previously herein in the context of the overlay metrology system 100 should be interpreted to extend to method 700. It is further noted, however, that the method 700 is not limited to the architecture of the overlay metrology system 100.

In embodiments, the method 700 includes a step 710 of generating, with an illumination source 116, illumination.

In embodiments, the method 700 includes a step 720 of directing, with an objective lens 124, one or more illumination beams 108 associated with the illumination to a metrology target 104 on a sample 106, wherein the metrology target 104 is configured in accordance with a metrology recipe to include periodic features associated with two or more lithographic exposures.

In embodiments, the method 700 includes a step 730 of collecting, with the objective lens 124, light associated with a first diffraction of the one or more illumination beams 108.

In embodiments, the method 700 includes a step 740 of receiving, with one or more optical assemblies 138, the light associated with the first diffraction of the one or more illumination beams 108.

In embodiments, the method 700 includes a step 750 of re-directing (e.g., reflecting), with the one or more optical assemblies 138, the light associated with the first diffraction of the one or more illumination beams 108 back towards the metrology target 104 on the sample 106.

In embodiments, the method 700 includes a step 760 of collecting, with the objective lens 124, twice-diffracted light 136 associated with a second diffraction of the one or more illumination beams 108. The second diffraction may include a subsequent diffraction of the light associated with the first diffraction of the one or more illumination beams 108 such that the light associated with the second diffraction includes a twice-diffracted light 136.

The method 700 may include an optional step of blocking, with a mask 208, a zero-order diffraction beam associated with each illumination beam 108 of the one or illumination beams 108. For example, the mask 208 may block all other diffraction orders except for a twice-diffracted +1-order and/or −1-order diffraction associated with each beam (e.g., allowing a +1-order diffraction associated with a first beam and a −1-order diffraction associated with a second beam). Additionally, other orders of diffraction may be diffracted outside of the collection pupil.

In embodiments, the method 700 includes a step 770 of generating, with a detector 132, an image of the metrology target 104 based on the twice-diffracted light 136 associated with the second diffraction of the one or more illumination beams 108.

In embodiments, the method 700 includes a step 780 of generating, with a controller communicatively coupled to the detector 132, one or more metrology measurements of the sample 106 based on the image in accordance with the metrology recipe. When zero-order diffraction is blocked by a mask 208, a dark field image may be generated for the metrology target 104.

The method 700 may further include a step of generating correctables for one or more process tools based on the one or more metrology measurements. For example, the correctables based on one or more metrology measurements may be used to control a fabrication tool using any combination of feed-forward or feedback control techniques. As an illustration, feedback control may be used to compensate for deviations of a fabrication tool for various samples within a lot or series of lots. As another illustration, feed-forward control may be used to compensate for deviations measured at one process step for a sample or series of samples when performing a subsequent process step. Any type of fabrication tool may be controlled such as, but not limited to, a lithography tool (e.g., a scanner, a stepper, or the like), an etching tool, or a polishing tool.

It is contemplated that when the sample has a metrology target with features having periodicity in a single measurement direction, a single pair of mutually coherent illumination beams, wherein the single pair of mutually-coherent illumination beams is incident on the metrology target at opposing azimuth angles aligned with the single measurement direction may be used to generate metrology measurements for the sample. Further, when the metrology target has a first set of periodic features along a first measurement direction and a second set of periodic features along a second measurement direction, two pairs of mutually coherent illumination beams may be required to fully perform metrology measurements. The two pairs of mutually coherent illumination beams may include a first pair of mutually coherent illumination beams, wherein the first pair of mutually coherent illumination beams is incident on the metrology target at opposing azimuth angles aligned with the first measurement direction and a second pair of mutually coherent illumination beams, wherein the second pair of mutually-coherent illumination beams is incident on the metrology target at opposing azimuth angles aligned with the second measurement direction.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed is:

1. An overlay metrology system configured for twice-diffracted light, the overlay metrology system comprising:
a controller configured to be communicatively coupled to a detector of an overlay metrology sub-system, wherein the controller comprises one or more processors configured to execute program instructions causing the one or more processors to:
receive an image of a metrology target of a sample based on twice-diffracted light associated with one or more illumination beams in accordance with a metrology recipe, wherein, in accordance with the metrology recipe, the twice-diffracted light is based on a first diffraction, a re-direction, and a second diffraction of the one or more illumination beams directed twice towards the metrology target; and
generate one or more metrology measurements of the sample based on the image in accordance with the metrology recipe and based on a double-phase-shift of the twice-diffracted light associated with the one or more illumination beams.

2. The overlay metrology system of claim 1, wherein the overlay metrology sub-system further comprises one or more masks, wherein the one or more masks are configured in accordance with the metrology recipe to pass a non-zero-order diffraction beam and block a zero-order diffraction beam associated with the twice-diffracted light associated with the one or more illumination beams.

3. The overlay metrology system of claim 1, wherein the one or more illumination beams comprise one or more pairs of mutually coherent illumination beams, wherein each illumination beam of the one or more pairs of the mutually coherent illumination beams is configured to be received by a respective set of one or more optical assemblies.

4. The overlay metrology system of claim 1, wherein, in accordance with the metrology recipe, the metrology target on the sample comprises an AIM metrology target.

5. An overlay metrology system configured for twice-diffracted light, the overlay metrology system comprising:
an illumination source configured to generate illumination;
an objective lens configured to direct one or more illumination beams associated with the illumination to a metrology target on a sample, wherein the metrology target is configured in accordance with a metrology recipe to include periodic features associated with two or more lithographic exposures, wherein the objective lens is further configured to collect light associated with a first diffraction of the one or more illumination beams;
one or more optical assemblies configured to receive the light associated with the first diffraction of the one or more illumination beams and to re-direct the light associated with the first diffraction of the one or more illumination beams back towards the metrology target on the sample, wherein the objective lens is further configured to collect twice-diffracted light associated with a second diffraction of the one or more illumination beams, wherein the second diffraction comprises a subsequent diffraction of the light associated with the first diffraction of the one or more illumination beams such that the light associated with the second diffraction comprises the twice-diffracted light;
a detector configured to generate an image of the metrology target based on the twice-diffracted light of the one or more illumination beams; and
a controller communicatively coupled to the detector, wherein the controller includes one or more processors configured to execute program instructions causing the one or more processors to generate one or more metrology measurements of the sample based on the image in accordance with the metrology recipe.

6. The overlay metrology system of claim 5, further comprising one or more masks, wherein the one or more masks are configured in accordance with the metrology recipe to pass a non-zero-order diffraction beam and block a zero-order diffraction beam associated with the twice-diffracted light of each of the one or more illumination beams.

7. The overlay metrology system of claim 6, wherein the one or more masks are located at or near a collection pupil of the overlay metrology system.

8. The overlay metrology system of claim 5, wherein each of the one or more optical assemblies comprises at least one focusing element.

9. The overlay metrology system of claim 8, wherein the at least one focusing element comprises at least one curved mirror.

10. The overlay metrology system of claim 8, wherein the at least one focusing element comprises at least one lens.

11. The overlay metrology system of claim 5, wherein the one or more illumination beams comprise one or more pairs of mutually coherent illumination beams, wherein each illumination beam of the one or more pairs of the mutually coherent illumination beams is configured to be received by a respective set of one or more optical assemblies.

12. The overlay metrology system of claim 5, wherein, in accordance with the metrology recipe, the metrology target on the sample comprises an AIM metrology target.

13. A metrology method comprising:
generating, with an illumination source, illumination;
directing, with an objective lens, one or more illumination beams associated with the illumination to a metrology target on a sample, wherein the metrology target is configured in accordance with a metrology recipe to include periodic features associated with two or more lithographic exposures;
collecting, with the objective lens, light associated with a first diffraction of the one or more illumination beams;
receiving, with one or more optical assemblies, the light associated with the first diffraction of the one or more illumination beams;
re-directing, with the one or more optical assemblies, the light associated with the first diffraction of the one or more illumination beams back towards the metrology target on the sample;
collecting, with the objective lens, twice-diffracted light associated with a second diffraction of the one or more illumination beams, wherein the second diffraction comprises a subsequent diffraction of the light associated with the first diffraction of the one or more illumination beams such that the light associated with the second diffraction comprises the twice-diffracted light;
generating, with a detector, an image of the metrology target based on the twice-diffracted light associated with the second diffraction of the one or more illumination beams; and
generating, with a controller communicatively coupled to the detector, one or more metrology measurements of the sample based on the image in accordance with the metrology recipe.

14. The metrology method of claim 13, further comprising:
passing, with one or more masks, a non-zero-order diffraction beam associated with the twice-diffracted light associated with each of the one or more illumination beams; and
blocking, with the one or more masks, a zero-order diffraction beam associated with the twice-diffracted light associated with each of the one or more illumination beams.

15. The metrology method of claim 14, wherein the one or more masks are located at or near a collection pupil of an overlay metrology system.

16. The metrology method of claim 13, wherein each of the one or more optical assemblies comprises at least one focusing element.

17. The metrology method of claim 16, wherein the at least one focusing element comprises at least one curved mirror.

18. The metrology method of claim 16, wherein the at least one focusing element comprises at least one lens.

19. The metrology method of claim 13, wherein the one or more illumination beams comprise one or more pairs of mutually coherent illumination beams, wherein each illumination beam of the one or more pairs of the mutually coherent illumination beams is configured to be received by a respective set of one or more optical assemblies.

20. The metrology method of claim 13, wherein, in accordance with the metrology recipe, the metrology target on the sample comprises an AIM metrology target.
